(19) United States
(12) Patent Application Publication
(10) Pub. No.: US 2004/0151224 A1
(43) Pub. Date: Aug. 5, 2004

(54) Distributed feedback semiconductor laser oscillating at longer wavelength mode and its manufacture method

(75) Inventors: Hirohiko Kobayashi, Kawasaki (JP); Hajime Shoji, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 10/747,305

(22) Filed: Dec. 30, 2003

(30) Foreign Application Priority Data
Feb. 5, 2003 (JP) 2003-028554

(51) Int. Cl. H01S 5/00; H01S 3/08

(52) U.S. Cl. 372/45; 372/96

(57) ABSTRACT

A lower quantum well structure is formed extending along a resonator direction, the lower quantum well structure being formed by alternately stacking lower barrier layers and lower well layers having a band gap narrower than a band gap of the lower barrier layers. An intermediate layer is disposed over the lower quantum well structure. The intermediate layer has a band gap broader than the band gap of the lower barrier layers. An upper quantum well structure is periodically disposed over the intermediate layer along the resonator direction. The upper quantum well structure is formed by alternately stacking upper well layers and upper barrier layers having a band gap broader than a band gap of the upper well layers. A distributed feedback semiconductor laser is provided which is not likely to oscillate in the mode at a shorter wavelength and is likely to oscillate in the mode at a longer wavelength.

### CROSS REFERENCE TO RELATED APPLICATION

This application is based on and claims priority of Japanese Patent Application No. 2003-028554 filed on Feb. 5, 2003, the entire contents of which are incorporated herein by reference.

### BACKGROUND OF THE INVENTION

A) Field of the Invention

The present invention relates to a semiconductor laser and its manufacture method, and more particularly to a distributed feedback type semiconductor laser having a diffraction grating for defining an oscillation wavelength and to its manufacture method.

B) Description of the Related Art

Backbone optical communication systems of long distance and large capacity transmission requires light sources excellent in single wavelength performance. The material of an optical fiber is inevitably associated with wavelength dispersion due to different refractive indices, i.e., different propagation velocities at different wavelengths. If this wavelength dispersion exists in a communication wavelength band, the waveform of an optical pulse is deformed as it propagates. If monochromaticity of a laser beam is intensified, it is possible to suppress the influence of wavelength dispersion and realize superior transmission characteristics.

A distributed feedback (DFB) semiconductor laser regulates an oscillation wavelength by a diffraction grating formed in the laser structure. It is therefore excellent in single wavelength performance. A typical structure of a DFB laser will be described with reference to the accompanying drawings.

FIGS. 8A and 8B are schematic diagrams showing the structure of a refractive index coupling type DFB laser. On the surface of an n-type semiconductor substrate 51, an n-type clad layer 52 is formed which has a periodical step structure and a relatively low refractive index. On the n-type clad layer 52, an n-type guide layer 53 is formed which buries the periodical step structure and has a relatively high refractive index. The clad layer 52 and guide layer 53 having different refractive indices form a diffraction grating.

On the n-type guide layer 53, a relatively low refractive index layer 54 and a quantum well active layer 55 are stacked in this order. The active layer 55 has a lamination structure formed by alternately stacking well layers W having the proper composition for a relatively long wavelength and a relatively high refractive index and barrier layers B having the proper composition for a relatively short wavelength and a relatively low refractive index. On the active layer 55, a relatively low refractive index p-type guide layer 56 is disposed. The lamination structure up to the p-type guide layer 56 is formed in a stripe-shaped mesa structure.

FIG. 8B shows the details of the structure near the n-type clad layer 52 and n-type guide layer 53. The n-type guide layer 53 has a higher refractive index than the n-type clad layer 52. Therefore, the periodical step structure of the clad layer 52 and guide layer 53 constitutes a periodical structure in terms of refractive index.

The quantum well active layer 55 including an alternate lamination of well layers W and barrier layers B is an active layer which amplifies light. A light distribution extends also the regions upper and lower than the active layer 55. Light components existing in the region lower than the active layer 55 are influenced by the periodical refractive index structure made of the clad layer 52 and guide layer 53. Namely, the periodical structure of the guide layer 53 and clad layer 52 serves as the diffraction grating.

Description continues by reverting to FIG. 8A. A p-type burying layer 61 and an n-type burying layer 62 are formed burying the peripheral region of the stripe-shaped mesa structure. These mesa structure and burying layers can be fabricated by forming a stripe-shaped hard mask of SiO₂ or the like on the p-type guide layer 56, performing mesa etching, thereafter performing selective growth on the exposed surface of semiconductor, and then removing the hard mask.

A p-type clad layer 63 and a p⁺-type contact layer 64 are formed on the p-type guide layer 56 and n-type burying layer 62. Insulating layers 65 of SiO₂ or the like are formed on the p⁺-type clad layer 64 on both sides of the stripe-shaped mesa structure. A p-side electrode 20 is formed on the contact layer 64 and insulating layers 65. The p-side electrode 20 contacts the contact layer 64 in an area where the insulating layers 65 are not formed, to inject current selectively. The current distribution is confined also by the burying layers 61 and 62 so that it concentrates upon the mesa structure region. An n-side electrode 19 is formed on the bottom surface of the substrate.

This DFB laser oscillates at a wavelength near a Bragg wavelength determined by the period of the diffraction grating so that this laser has intensified monochromaticity of laser beams.

The diffraction grating such as that shown in FIG. 8B has thick and thin regions of the n-type guide layer 53. Two longitudinal modes exist which depend upon which one of the thick and thin regions corresponds to an antinode of a standing wave. More specifically, the DFB laser shown in FIGS. 8A and 8B does not oscillate correctly at the Bragg wavelength, but it oscillates on a longer or shorter wavelength side having a higher probability or it oscillates in two modes at the same time.

A structure (λ/4 shift structure) has been proposed to restrict an oscillation mode by forming a ¼ wavelength shift structure in the middle area of a diffraction grating. In order to stably oscillate this laser device at a Bragg wavelength, it is necessary to eliminate the influence of light reflected at an end face of the resonator. If light reflected from the end face returns back to the diffraction grating region, the phase of the diffraction grating and the phase of the reflected light are interfered each other.

In order to remove reflected light, it is necessary to form a non-reflection (antireflection) film on both end faces of the resonator. With the non-reflection films formed on both end faces, light is emitted from both end faces approximately equal in quantity. This light use factor is about a half of that of a light source which uses light emitted only from one end face. There is another problem of an unstable oscillation spectrum if external light enters the laser device.

A gain coupling DFB laser (complex coupling DFB laser) has been proposed which has an oscillation spectrum having a higher stability than a refractive index coupling DFB laser.

FIG. 9B is a schematic diagram showing the structure of a gain coupling DFB laser. On an n-type clad layer 72, barrier layers 73 (B) and well layers 74 (W) are alternately stacked to form a multiple quantum well structure 75 having the barrier layers 73 as the uppermost and lowermost layers.

The barrier layers 73 (B) and well layers 74 (W) are periodically removed along a longitudinal direction of the optical resonator, down to the intermediate depth of the multiple quantum well structure 75. In the structure shown in FIG. 9A, these layers are removed down to the middle depth of the fourth barrier layer 73 (B). A p-type guide layer 76 is formed covering this periodical structure. On the p-type guide layer 76, a p-type clad layer 77 is disposed.

In the gain coupling DFB laser, the multiple quantum well structure itself is periodically removed to form a diffraction grating. Since carriers are laterally injected into the well layers 74 (W) constituting the diffraction grating, a current injection gain changes periodically along the longitudinal direction of the resonator so that a large gain coupling coefficient can be obtained.

The position (antinode) of a large amplitude of a standing wave generated along the longitudinal direction of the resonator of a gain coupling DFB laser is fixed to a position where the gain is large. Therefore, this laser is not susceptible to the influence of external return light and the oscillation spectrum is stable. Since this laser is also not susceptible to the influence of the phase of end face reflected light, disturbance of the spectrum is small even if an asymmetrical resonator structure is adopted which has a non-reflection film formed only on the output end face and a high reflection film formed on the opposite end face. A high output operation is therefore possible.

The manufacture processes for an active layer of such a gain coupling DFB laser will be described with reference to FIGS. 9B to 9D.

As shown in FIG. 9B, a multiple quantum well structure 75 is formed by alternately stacking barrier layers 73 (B) having a large band gap and well layers 74 (W) having a narrow band gap. On the surface of the multiple quantum well structure 75, a resist mask 80 is formed which has a periodical structure.

As shown in FIG. 9C, by using the resist mask 80 as an etching mask, the multiple quantum well structure 75 is etched down to an intermediate depth thereof. This etching is stopped at the intermediate barrier layer 73 (B). The resist mask 80 is removed thereafter.

As shown in FIG. 9D, a p-type guide layer 76 is grown burying the step region of the multiple quantum well structure 75 partially etched to have the periodical structure. Thereafter, mesa etching is performed, and burying layers, a clad layer, a contact layer and the like are formed. The multiple quantum well structure having the periodical structure such as that shown in FIG. 9A can be manufactured.

The active layer itself having a high refractive index is processed for a gain coupling DFB laser. A complex coupling diffraction grating can therefore be formed which has both refractive index modulation and gain modulation along the longitudinal direction of the resonator. Such a complex coupling DFB laser is likely to oscillate in the mode at the wavelength longer than the Bragg wavelength.

In a complex coupling DFB laser, carriers are injected into the etched upper well layers W along the lateral direction. It is therefore possible to obtain a large gain coupling coefficient and a refractive index coupling coefficient smaller than that of a mesa structure with all well layers in the active layer being etched. The above-described merit of the complex coupling DFB laser can therefore be enhanced.

Japanese Patent Laid-open Publication No. 2001-332809 discloses a DFB laser which has one thick barrier layer among barrier layers of the resonator to stop etching in this thick barrier layer with good reproductivity.

Japanese Patent Laid-open Publication No. HEI-6-85402 describes related techniques which are also incorporated herein by reference.

### SUMMARY OF THE INVENTION

As described above, a gain coupling DFB laser is likely to oscillate in the mode at a longer wavelength than a Bragg wavelength of the resonator.

Current flowed into upper well layers W uniformly flows thereafter into lower well layers W where the diffraction grating is not formed. Therefore, the well layers 74 (W) (well layers in the concave part) left under the regions etched in the process shown in FIG. 9C have also a gain. The gain coupling DFB laser can oscillate therefore in the mode at a shorter wavelength with the antinode of a standing wave being positioned in the well layers in the concave part.

It is an object of the present invention to provide a distributed feedback semiconductor laser which is likely to oscillate in the mode at a shorter wavelength than in the mode at a longer wavelength and its manufacture method.

According to one aspect of the present invention, there is provided a distribution feedback semiconductor laser comprising: a lower quantum well structure extending along a resonator direction, the lower quantum well structure being formed by alternately stacking lower barrier layers and lower well layers having a band gap narrower than a band gap of the lower barrier layers; an intermediate layer disposed over the lower quantum well structure and having a band gap broader than the band gap of the lower barrier layers; and an upper quantum well structure periodically disposed over the intermediate layer along the resonator direction, the upper quantum well structure being formed by alternately stacking upper well layers and upper barrier layers having a band gap broader than a band gap of the upper well layers.

Since the band gap of an intermediate layer is set larger than that of the lower barrier layer, a gain of the upper quantum well structure can be made high so that the laser is likely to oscillate in the mode at a longer wavelength with the antinode being set to the upper quantum well structure.

It is possible to improve a manufacture yield of DFB laser devices capable of oscillating in the mode at a longer wavelength.

### BRIEF DESCRIPTION OF THE DRAWINGS

FIG. 1 is a perspective view partially broken of a DFB laser according to an embodiment.

FIGS. 2A to 2C are cross sectional views illustrating a method of forming an active layer of a DFB laser according to an embodiment.

FIG. 3 is a perspective view partially broken of a DFB laser according to another embodiment.

FIGS. 4A to 4D are respectively an energy band diagram, a hole density graph, an electron density graph and a gain distribution graph at the position where the upper quantum well active layers are disposed and at the band gap wavelength of 1.1 μm for both the intermediate layer and barrier layers, and FIGS. 4E to 4H are respectively an energy band diagram, a hole density graph, an electron density graph and a gain distribution graph at the position where the upper quantum well active layers are disposed and at the band gap wavelength of 1.0 μm for the intermediate layer and 1.1 μm for the barrier layers.

FIGS. 5A to SD are respectively an energy band diagram, a hole density graph, an electron density graph and a gain distribution graph at the position where the upper quantum well active layers are not disposed and at the band gap wavelength of 1.1 μm for both the intermediate layer and barrier layers, and FIGS. 5E to 5H are respectively an energy band diagram, a hole density graph, an electron density graph and a gain distribution graph at the position where the upper quantum well active layers are not disposed and at the band gap wavelength of 1.0 μm for the intermediate layer and 1.1 μm for the barrier layers.

FIGS. 6A and 6E are energy band diagrams, FIGS. 6B and 6F are hole density graphs, FIGS. 6C and 6G are electron density graphs and FIGS. 6D and 6H are gain graphs at a band gap wavelength of 1.05 μm for the intermediate layer.

FIG. 7 is a cross sectional view of an active layer and its nearby structure according to a modification of the embodiment.

FIGS. 8A and 8B are a perspective view partially broken and a cross sectional view, respectively of a conventional DFB laser.

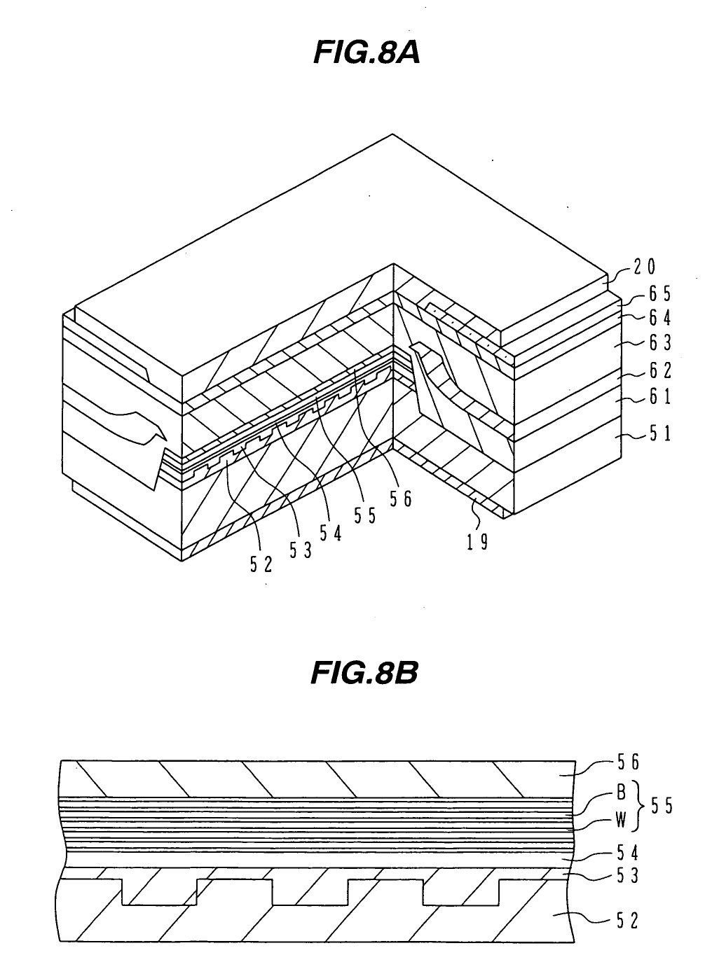

FIGS. 9A to 9D are cross sectional views illustrating a method of forming an active layer of a conventional DFB laser.

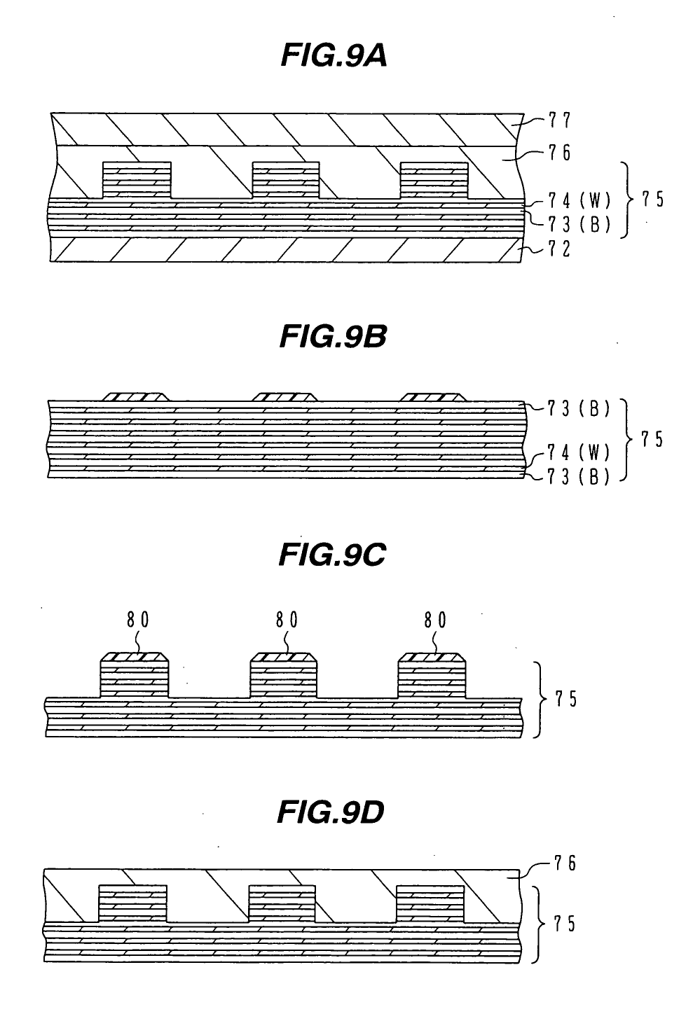

### DESCRIPTION OF THE PREFERRED EMBODIMENTS

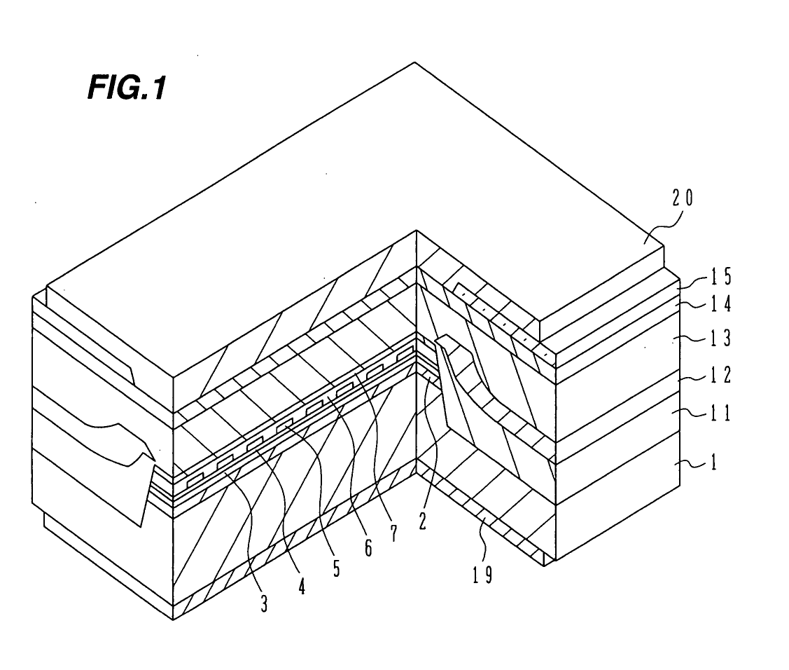

FIG. 1 is a perspective view partially broken of a DFB laser according to the first embodiment of the invention. The manufacture method for a DFB laser will be described by taking a gain coupling DFB laser for a 1.3 μm band as an example.

An n-type InP buffer layer 2 having a thickness of 0.1 μm and doped with Si at 5×10¹⁷ cm⁻³ is formed by metal organic vapor phase epitaxy (MOVPE) on the surface of an n-type InP substrate which contains n-type impurities Si at 1×10¹⁸ cm⁻³. On the n-type InP buffer layer 2, a lower quantum well active layer 3 is formed. The n-type InP buffer layer 2 and n-type InP substrate 1 serve also as an n-side clad layer.

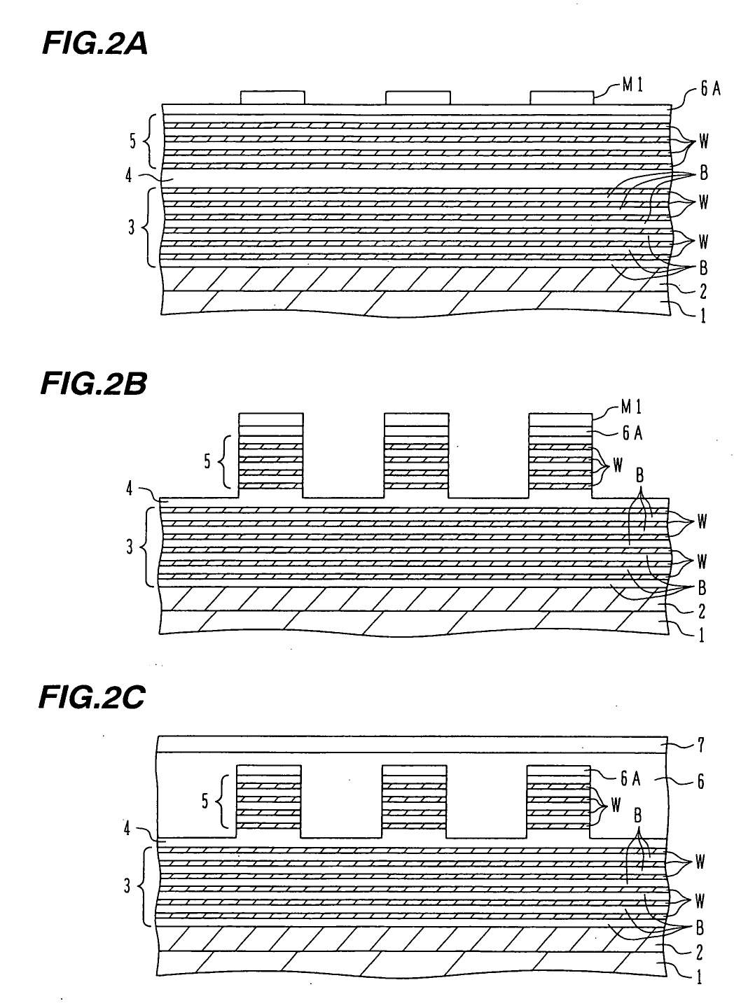

As shown in FIG. 2A, the lower quantum well active layer 3 is formed by alternately laminating barrier layers B having a thickness of 10 nm and no strain and well layers W having a thickness of 4 nm and strain. Six barrier layers B in total are disposed, and six well layers W in total are disposed. Each barrier layer B is made of InGaAsP having the composition which sets the wavelength corresponding to the band gap to 1.1 μm, and each well layer W is made of InGaAsP having the composition, in which the wavelength corresponding to the band gap is 1.3 μm. The band gap of the well layers W is narrower than that of the barrier layers B.

An intermediate layer 4 made of non-doped InGaAsP and having a thickness of 50 nm is formed on the lower quantum well active layer 3. The intermediate layer 4 has the composition, in which the wavelength corresponding to the band gap is 1.0 μm. The band gap of the intermediate layer 4 is broader than that of the barrier layers B.

On the intermediate layer 4, an upper quantum well active layer 5 is formed. The upper quantum well active layer 5 has the structure that four well layers W and four barrier layers B are alternately stacked. The film thicknesses and compositions of respective well layers W and barrier layers B are the same as those of respective well layers W and barrier layers B of the lower quantum well active layer 3.

A non-doped InP layer 6A having a thickness of 50 nm is formed on the upper quantum well active layer 5. On the InP layer 6A, a resist mask M1 is formed. The resist mask M1 can be formed by coating resist material, performing two-beam interference exposure and thereafter developing the resist film. Interference between two light beams forms the resist mask M1 having a regularly repeating stripe pattern. The pitch of stripes defines a lattice constant of a diffraction grating.

As shown in FIG. 2B, by using the resist mask M1 as an etching mask, reactive ion etching (RIE) is performed using etchant gas which contains methane to anisotropically etch the upper quantum well active layer 5. The etching is stopped by time control when the etching progresses down to the intermediate depth of the intermediate layer 4. The etching time was set to 3 minutes and 50 seconds. The etching can be stopped in the intermediate layer 4 with good reproductivity because the intermediate layer 4 is thicker than the barrier layers B in the upper and lower quantum well active layers 5 and 3. The resist mask M1 is thereafter removed. The upper quantum well active layer 5 has a periodical pattern based upon a constant lattice constant determined by the resist mask M1 to thereby form a diffraction grating.

As shown in FIG. 2C, a diffraction grating burying layer 6 of non-doped InP is grown by MOVPE, burying the upper quantum well active layer 5. The band gap of the diffraction grating burying layer 6 is broader than that of the well layers W. A thickness of the diffraction grating burying layer 6 is set to 50 nm as measured on the upper quantum well active layer 5. On the diffraction grating burying layer 6, a p-type clad layer 7 is formed which is made of p-type InP and having a thickness of 200 nm. The upper surface of the p-type clad layer 7 is generally flat.

Description continues by reverting to FIG. 1. On the p-type clad layer 7, an SiO₂ film is formed which has a stripe shape along the in-plane direction perpendicular to each of the diffraction grating patterns. By using this SiO₂ film as an etching mask, etching is performed to leave the upper quantum well active layer 5, intermediate layer 4 and lower quantum well active layer 3 at a width of about 1.2 μm. A mesa structure is therefore formed.

By leaving the SiO₂ film used as the etching mask, crystal growth is performed twice by MOVPE to form a p-type inP burying layer 11 and an n-type InP burying layer 12. The SiO₂ film is thereafter removed.

A p-type InP clad layer 13 and a p⁺-type InGaAs contact layer 14 are grown by MOVPE. On the contact layer 14, an SiO₂ film 15 is formed which has an opening corresponding to the mesa structure. A p-side electrode 20 is formed on the SiO₂ film 15 and exposed contact layer 14. The p-side electrode 20 has, for example, a three-layer structure stacking a Ti layer, a Pt layer and an Au layer in this order.

On the bottom surface of the substrate 1, an n-side electrode 19 is formed. The n-side electrode 19 has, for example, a two-layer structure stacking an AuGe layer and an Au layer in this order. Thereafter, cleavage is performed to form an optical resonator and a laser structure. A non-reflection film is coated on an output end face of the optical resonator and a high reflection film is coated on the opposite end face.

In this embodiment, the band gap wavelength of the intermediate layer 4 is 1.0 μm which is shorter than the band gap wavelength of 1.1 μm of the barrier layers B of the lower and upper quantum well active layers 3 and 5. The band gap of the intermediate layer 4 is broader than that of the barrier layer B.

A plurality of laser devices having the embodiment structure described above were manufactured and the oscillation spectra were measured. About 95% of the laser devices oscillated in the mode at the longer wavelength. For the purposes of comparison, a plurality of laser devices with the band gap of the intermediate layer 4 being set equal to that of the barrier layers B were manufactured and the oscillation spectra were measured. 80% of the laser devices oscillated in the mode at the longer wavelength. It can be seen from these evaluation results that the manufacture yield of DFB laser devices oscillating in the mode at the longer wavelength can be improved by making the band gap of the intermediate layer 4 broader than that of the barrier layer B.

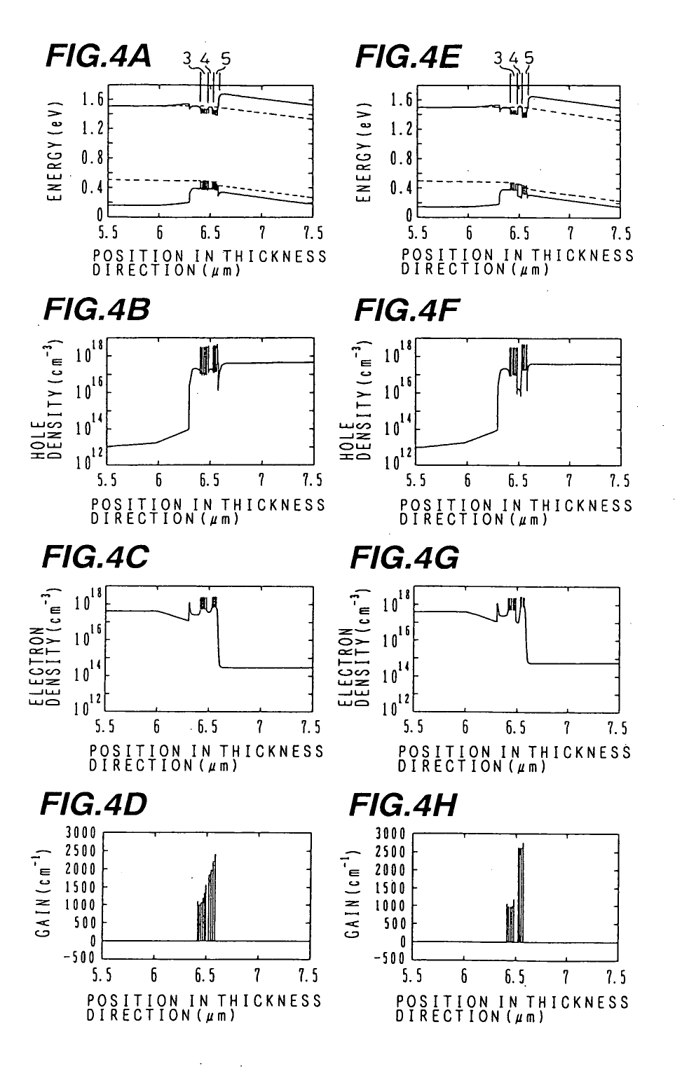

With reference to FIGS. 4A to 6H, description will be made on the reason why the oscillation in the mode at the longer wavelength becomes easy by adopting the embodiment structure.

FIGS. 4A and 4E are energy band diagrams of a laser device (comparative example) in which the band gap wavelength of the intermediate layer 4 is 1.1 μm (equal to that of the barrier layers B) and a laser device (embodiment) in which the band gap wavelength of the intermediate layer 4 is 1.0 μm. The abscissa represents a position in a thickness direction in the unit of “μm”, the left side corresponding to the substrate side.

FIGS. 4B and 4F are respectively diagrams showing a hole density distribution of the laser devices according to the comparative example and embodiment. FIGS. 4C and 4G are respectively diagrams showing an electron hole density distribution of the laser devices according to the comparative example and embodiment. FIGS. 4D and 4H are respectively diagrams showing a gain distribution of the laser devices according to the comparative example and embodiment.

As understood from the comparison between FIGS. 4A and 4E, in the case of the embodiment, a potential barrier is formed between the upper and lower quantum well active layers 5 and 3 at both band ends of the conduction band and valence band. Holes injected from the p-type region (right side in the drawings) into the active layer have a relatively large effective mass so that there is a low probability that the holes hurdle the potential barriers. Therefore, as understood from the comparison between FIGS. 4B and 4F, in the case of the embodiment, the hole density in the upper quantum well layer 5 is high.

In contrast, electrons injected from the n-side region (left side in the drawings) into the active layer have a relatively small effective mass so that the electrons are easy to hurdle the potential barriers. Therefore, as understood from the comparison between FIGS. 4C and 4G, a difference of the electron density is not so large between the embodiment and comparative example. The hole density of the upper quantum well active layer 5 of the laser device of the embodiment increases accordingly.

As shown in FIGS. 4D and 4H, the gain of the upper quantum well active layer 5 of the embodiment laser device becomes higher than that of the comparative example.

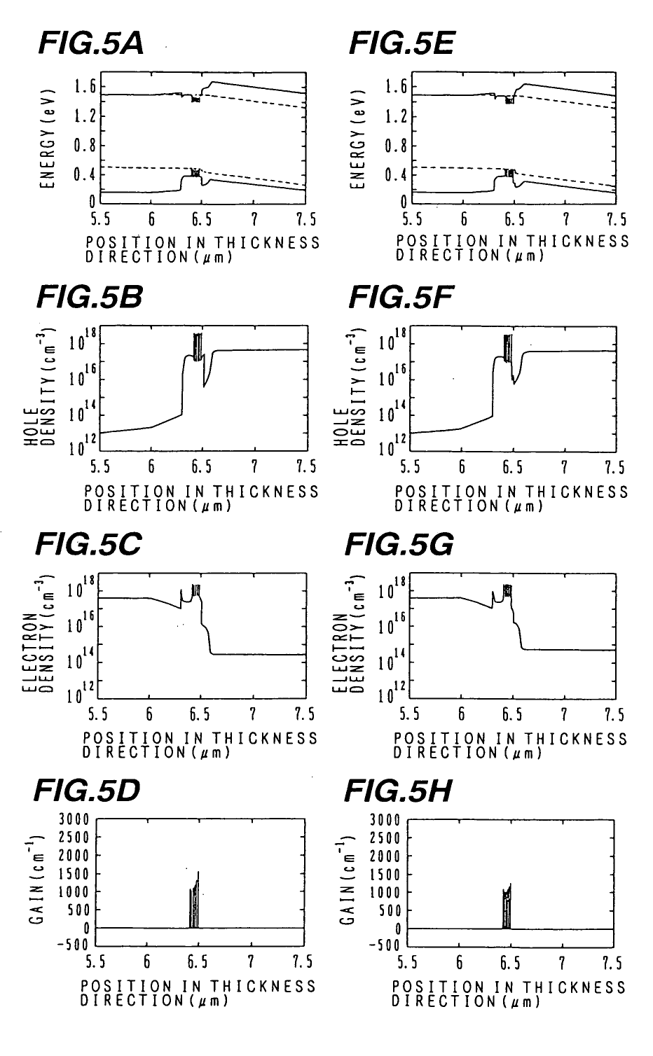

FIGS. 5A to 5H are energy band diagrams, hole density graphs, electron density graphs and gain graphs at the position (concave part of the diffraction grating) where the upper quantum well active layer 5 is not disposed. FIGS. 5A to 5D are for the comparative example, and FIGS. 5E to 5H are for the embodiment.

It can be understood from the comparisons between FIGS. 4D and 5D and between FIGS. 4H and 5H that a large difference of the carrier densities and gain of the lower quantum well active layer 3 does not exist between the region (convex part of the diffraction grating) where the upper quantum well active layer 5 is disposed and the concave part.

In the embodiment, therefore, since the gain of the upper quantum well active layer 5 increases, a difference of the gain becomes large between the convex part and concave part regions of the diffraction grating. Oscillation in the mode at the shorter wavelength is therefore suppressed and oscillation in the mode at the longer wavelength becomes likely to occur.

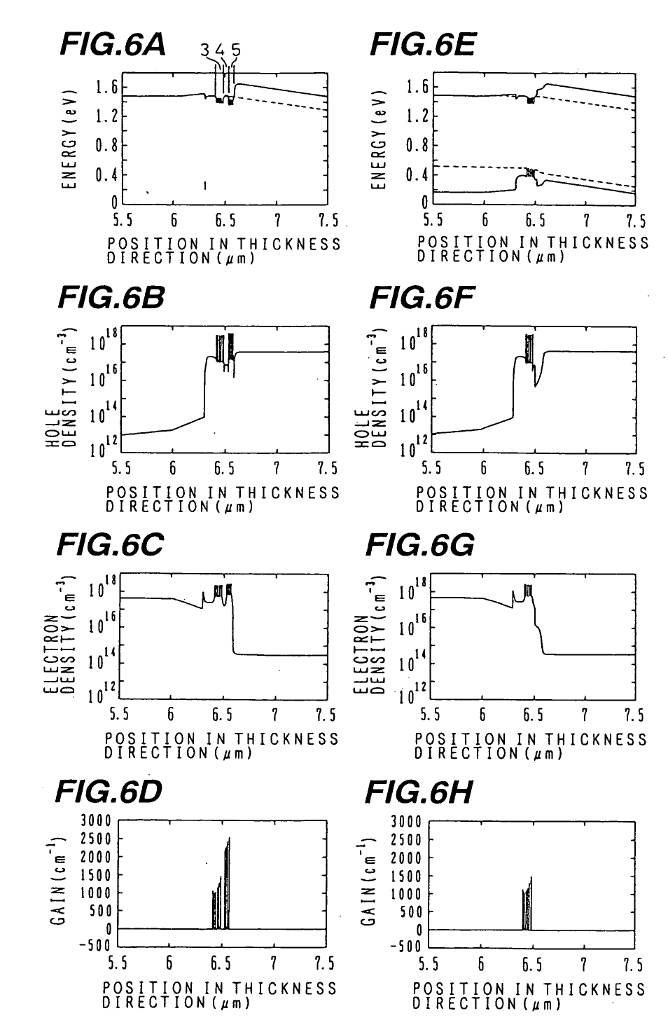

FIGS. 6A to 6H are respectively energy band diagrams, hole density graphs, electron density graphs and gain graphs, with the band gap wavelength of the intermediate layer 4 shown in FIG. 2C being set to 1.05 μm. FIGS. 6A to 6D are for the convex part of the diffraction grating, and FIGS. 6E to 6H are for the concave part.

It can be understood from the comparison between the gain distribution shown in FIG. 6D and that shown in FIGS. 4D and 4H that the gain of the upper quantum well active layer 5 is lower than that shown in FIG. 4H and surely higher than that shown in FIG. 4D. Even if the band gap wavelength of the intermediate layer 4 is set to 1.05 μm, a large difference of the gain can be obtained between the concave part and convex part of the diffraction grating.

As in the embodiment, a gain difference between the convex part and concave part of the diffraction grating can be made large by making the band gap of the intermediate layer 4 broader than that of the barrier layers B of the lower and upper quantum well active layers 3 and 5. It is therefore possible to suppress oscillation in the mode at the shorter wavelength and give a preference to oscillation in the mode at the longer wavelength. It is preferable to set a difference of the band gap wavelength between the barrier layers B and intermediate layer 4 to 0.05 μm or longer.

In the embodiment, although the intermediate layer 4 is made thicker than the barrier layers B of the lower and upper quantum well active layers 3 and 5, the thickness of the intermediate layer 4 may be the same as that of the barrier layers B.

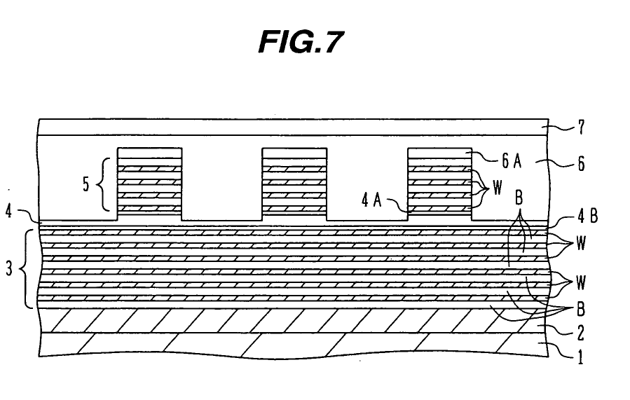

FIG. 7 is a cross sectional view of an active layer and its nearby layers of a DFB laser according to a modification of the embodiment. In this modification, a first thin film 4B of InGaAsP is disposed between an intermediate layer 4 and a lower quantum well active layer 3, and a second thin film 4A of InGaAsP is disposed between the intermediate layer 4 and an upper quantum well active layer 5. The first and second thin films 4B and 4A have the intermediate composition between those of the intermediate layer 4 and barrier layer B.

In the embodiment shown in FIG. 2C, notches are formed on both sides of the intermediate layer 4 on the valence band side, as shown in FIG. 4E. Such notches cause an increase in a device resistance. By disposing the first and second thin films 4B and 4A as shown in FIG. 7, notches to be formed on both sides of the intermediate layer 4 can be reduced.

The embodiment has been described by using a DFB laser of a mesa type structure by way of example. A DFB laser of a structure different from the mesa type may also be manufactured. Each of the first and second thin films 4B and 4A may be made of a plurality of layers whose compositions change stepwise.

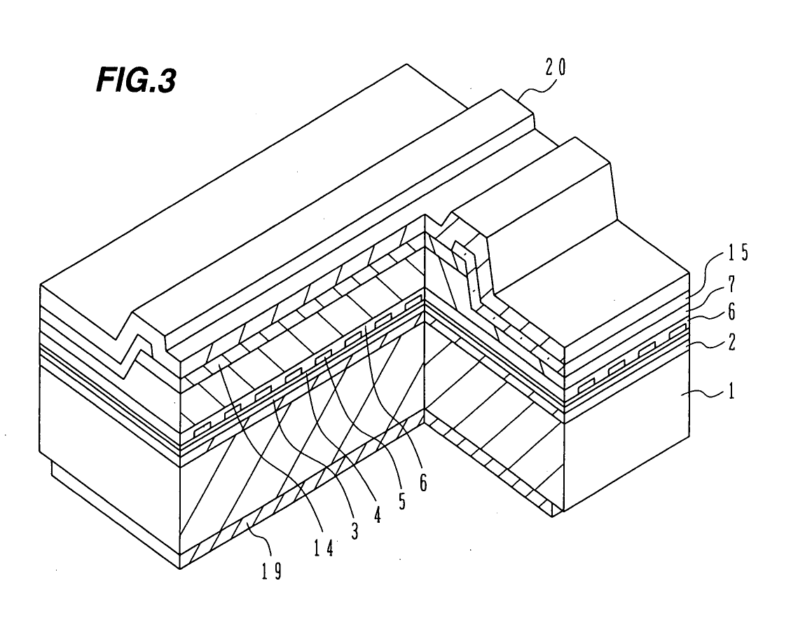

FIG. 3 shows an example of the structure of a ridge type DFB laser. After an n-type InP buffer layer 2 is grown on an n-type InP substrate 1, a lower quantum well active layer 3, an intermediate layer 4 and an upper quantum well active layer 5 are grown in this order. The upper quantum well active layer 5 constitutes a diffraction grating. A diffraction grating burying layer 6 is grown covering the diffraction grating. These manufacture processes are similar to those of the embodiment shown in FIG. 1.

On the diffraction grating burying layer 6, a p-side clad layer 7 of p-type InP and a p-side contact layer 14 of p⁺-type InGaAs are grown. On the contact layer 14, a stripe-shaped mask is formed and the contact layer 14 and clad layer 7 are anisotropically etched. The whole thickness of the contact layer 14 and a partial thickness of the clad layer 7 are removed from the regions outside of the stripe. A ridge including the clad layer 7 and contact layer 14 is therefore left.

A refractive index distribution is formed along the direction perpendicular to the ridge extending direction so that the ridge is provided with the light confinement effect.

After an SiO₂ film 15 is formed having an opening corresponding to an electrode contact upper surface of the ridge, a p-side electrode 20 is formed. An n-side electrode 19 is formed on the bottom surface of the substrate 1. Each electrode may have the structure similar to that of the embodiment shown in FIG. 1.

In the embodiments, the laser device is manufactured by using an n-type substrate and forming an n-type region at a lower level and a p-type region at an upper level. A laser device may be manufactured by using a p-type substrate and forming a p-type region at a lower level and an n-type region at an upper level. Although a semiconductor laser for the 1.3 μm band is manufactured, a semiconductor laser for a different wavelength band may also be manufactured. For example, a semiconductor laser of a 1.55 μm band may be manufactured by changing the compositions of well layers, barrier layers and an intermediate layer.

The present invention has been described in connection with the preferred embodiments. The invention is not limited only to the above embodiments. It will be apparent to those skilled in the art that other various modifications, improvements, combinations, and the like can be made.

What we claim are:

1. A distribution feedback semiconductor laser comprising:
a lower quantum well structure extending along a resonator direction, the lower quantum well structure being formed by alternately stacking lower barrier layers and lower well layers having a band gap narrower than a band gap of the lower barrier layers;
an intermediate layer disposed over the lower quantum well structure and having a band gap broader than the band gap of the lower barrier layers; and
an upper quantum well structure periodically disposed over the intermediate layer along the resonator direction, the upper quantum well structure being formed by alternately stacking upper well layers and upper barrier layers having a band gap broader than a band gap of the upper well layers.

2. The distributed feedback semiconductor laser according to claim 1, wherein the lower well layers and the upper well layers have a first band gap, the intermediate layer has a second band gap, and a difference between a wavelength corresponding to the first band gap and a wavelength corresponding to the second band gap is 0.05 μm or longer.

3. The distributed feedback semiconductor laser according to claim 1, wherein the intermediate layer is thicker than each of the lower barrier layers and the upper barrier layers..

4. The distributed feedback semiconductor laser according to claim 1, further comprising a diffraction grating burying layer covering the upper quantum well structure and disposed over the intermediate layer, the diffraction grating burying layer having a band gap broader than band gaps of the lower well layers and the upper well layers.

5. The distributed feedback semiconductor laser according to claim 1, further comprising a first thin film disposed between the intermediate layer and the lower quantum well structure, the first thin film having an intermediate composition between compositions of the lower barrier layers and the intermediate layer.

6. The distributed feedback semiconductor laser according to claim 1, further comprising a second thin film disposed between the intermediate layer and the upper quantum well structure, the second thin film having an intermediate composition between compositions of the upper barrier layers and the intermediate layer.

7. The distributed feedback semiconductor laser according to claim 1, further comprising a substrate supporting the lower quantum well structure, wherein the upper quantum well structure, the intermediate layer and the lower quantum well structure constitute a stripe-shaped mesa over the substrate.

8. The distributed feedback semiconductor laser according to claim 1, further comprising a substrate supporting the lower quantum well structure, wherein the upper quantum well structure, the intermediate layer and the lower quantum well structure are disposed over a whole surface of the substrate; and further comprising a clad layer constituting a stripe-shaped mesa over the upper quantum well structure.

9. A method of manufacturing a distributed semiconductor laser comprising the steps of:
forming a lower quantum well structure by alternately stacking, over a semiconductor substrate, lower barrier layers and lower well layers having a band gap narrower than a band gap of the lower barrier layers;
forming an intermediate layer over an uppermost lower well layer, the intermediate layer having a band gap broader than the band gap of the lower barrier layers;
forming an upper quantum well structure by alternately stacking, over the intermediate layer, upper well layers and upper barrier layers having a band gap broader than a band gap of the upper well layers;
forming a mask having a periodical pattern on the upper quantum well structure;
forming a diffraction grating through etching reaching at least the intermediate layer and not reaching the lower quantum well structure by using the mask as an etching mask; and
removing the mask.

10. The method of manufacturing a distributed feedback semiconductor laser according to claim 9, further comprising a step of:
after the step of removing the mask, growing a diffraction grating burying layer over the intermediate layer, so as to cover the etched upper quantum well structure, the diffraction grating layer having a band gap broader than band gaps of the upper well layers and the lower well layers.
